(19) United States
(12) Patent Application Publication
(10) Pub. No.: US 2025/0391700 A1
(43) Pub. Date: Dec. 25, 2025

(54) HYBRID VACUUM ELECTROSTATIC CHUCK

(71) Applicant: Applied Materials, Inc., Santa Clara, CA (US)

(72) Inventors: Jian LI, Fremont, CA (US); Ganesh BALASUBRAMANIAN, Fremont, CA (US); Juan C. ROCHA, San Carlos, CA (US)

(21) Appl. No.: 18/750,718

(22) Filed: Jun. 21, 2024

(51) Int. Cl. B23Q 3/15; B23Q 3/08; H02N 13/00

(52) U.S. Cl. CPC H01L 21/6838; H01L 21/6833

(57) ABSTRACT

Embodiments of the present invention generally relate to a substrate chucking apparatus having both vacuum and electrostatic chucking functions and related methods. In one or more embodiments, a substrate chucking apparatus incudes a body having a chucking surface and a shaft coupled to the body opposite to the chucking surface. The substrate chucking apparatus further includes a chucking electrode disposed within the body and a vacuum channel formed within the body.

### BACKGROUND

### Field

Embodiments of the present invention generally relate to a substrate chucking apparatus having both vacuum and electrostatic chucking functions and related methods.

### Description of the Related Art

Substrate chucking apparatus are commonly used in the semiconductor and display industries to support a substrate during transfer or processing of the substrate. Various semiconductor packaging and manufacturing techniques may result in a high degree of substrate bowing, such as a compressive bow.

Substrate chucking apparatuses includes both vacuum chucking apparatuses and electrostatic chucking (ESC) apparatuses. Both types of chucking apparatuses work most effectively when a substrate substantially lays flat against the chucking apparatus and the substrate has many points of contact with the substrate chucking apparatus. Substrates with a compressive bow often cause the center of the substrate to be a distance from the substrate chucking apparatus when the substrate is disposed on the substrate chucking apparatus for chucking. This distance makes it difficult for both vacuum and ESC chucking apparatuses to effectively chuck the substrate.

Thus, what is needed in the art are improved techniques for chucking a substrate.

### SUMMARY

Embodiments of the present invention generally relate to a substrate chucking apparatus with both vacuum and electrostatic chucking functions and related methods.

In one or more embodiments, a substrate chucking apparatus incudes a body having a chucking surface and a shaft coupled to the body opposite to the chucking surface. The substrate chucking apparatus further includes a chucking electrode disposed within the body and a vacuum channel formed within the body.

In one or more embodiments, a substrate processing chamber includes a chamber body at least partially defining a processing region. A chamber pump is fluidly coupled to the processing region. A substrate support assembly disposed within the processing region. The substrate support assembly includes a substrate chucking apparatus having a chucking surface. A shaft is coupled to the substrate chucking apparatus opposite to the chucking surface. A chucking electrode is disposed within the substrate chucking apparatus and a vacuum channel is formed within the substrate chucking apparatus.

In one or more embodiments, a method of chucking a substrate includes positioning a substrate on a chucking surface of a chucking apparatus disposed within a processing chamber and activating a pump to create a vacuum between the chucking surface and the substrate. The method further includes applying a voltage to a chucking electrode disposed within the chucking apparatus to chuck the substrate to the chucking surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic sectional view of a processing chamber, according to one or more embodiments.

FIG. 1B is an enlarged partial view of the substrate support assembly of the processing chamber of FIG. 1. 1A, according to one or more embodiments.

FIG. 2 is a flow diagram of a method for chucking a substrate, according to one or more embodiments.

FIGS. 3A-3E show schematic cross sectional views of the hybrid chuck of FIG. 1B during the method of FIG. 2, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to a substrate chucking apparatus having both vacuum and electrostatic chucking functions and related methods.

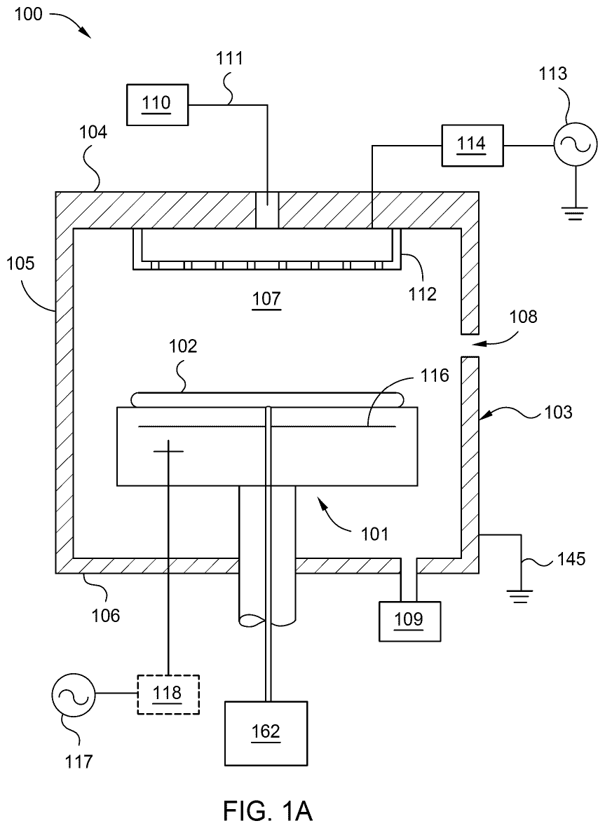

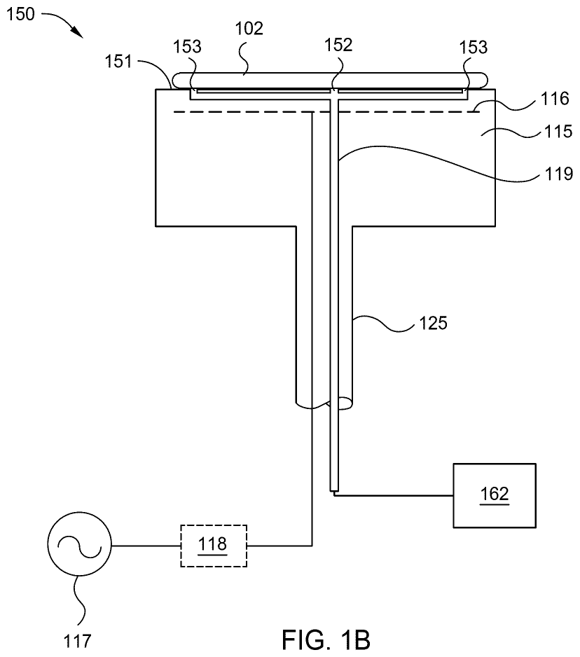

FIG. 1A is a schematic sectional view of a processing chamber 100, according to one or more embodiments. The processing chamber 100 includes a substrate support assembly 101 on which a substrate 102 is processed. The processing chamber 100 may be a chemical vapor deposition (CVD) processing chamber, a physical vapor deposition (PVD) processing chamber, a hot wire chemical vapor deposition (HWCVD) processing chamber, an etch chamber, or another chamber for processing substrates.

The processing chamber 100 includes a chamber body 103 having a top 104, chamber sidewalls 105, and a chamber bottom 106 which are coupled to a ground 145. The top 104, the chamber sidewalls 105, and the chamber bottom 106 define an interior processing region 107. The chamber sidewalls 105 may include a substrate transfer port 108 to facilitate transferring the substrate 102 into and out of the processing chamber 100. The substrate transfer port 108 may be coupled to a transfer chamber and/or other chambers of a substrate processing system.

The dimensions of the chamber body 103 and related components of the processing chamber 100 are not limited and generally are proportionally larger than the size of the substrate 102 to be processed therein. Examples of substrate sizes include 200 mm diameter, 250 mm diameter, 300 mm diameter, and 450 mm diameter, among others.

In some embodiments, a chamber pump 109 is coupled to the bottom 106 of the processing chamber 100 to evacuate and control the pressure with the processing chamber 100. The chamber pump 109 may be a conventional roughing pump, roots blower, turbo pump, or other similar device that is adapted to control the pressure in the interior processing region 107. In various embodiments, the pressure within the interior processing region 107 of the processing chamber 100 may be maintained at less than about 760 Torr.

A gas panel 110 supplies process, precursor gases, and other gases through a gas line 111 into the interior processing region 107 of the chamber body 103. The gas panel 110 may be configured to provide one or more process gas sources, cleaning gases, inert gases, non-reactive gases, and reactive gases, if desired. A showerhead 112 is disposed below the top 104 of the processing chamber 100 and is spaced above the substrate support assembly 101. As such, the showerhead 112 is above the substrate 102 when the substrate 102 is positioned on the substrate support assembly 101 for processing. One or more process gases provided from the gas panel 110 may supply reactive species through the showerhead 112 into the interior processing region 107. The showerhead 112 also functions as an electrode for coupling power to gases within the interior processing region 107, for example, for generating ionized species from the gases. It is contemplated that power may be coupled to the gases within the interior processing region 107 utilizing other electrodes or devices.

A power supply 113 may be coupled through a match circuit 114 to the showerhead 112. In one example, the power supply 113 may supply high frequency RF energy to the showerhead 112. The energy applied to the showerhead 112 from the power supply 113 is inductively coupled to the process gases disposed in the interior processing region 107 to maintain a plasma region in the processing chamber 100. Alternatively, or in addition to the power supply 113, power may be capacitively coupled to the process gases in the interior processing region 107 to maintain the plasma within the interior processing region 107. The operation of the power supply 113 may be controlled by a controller, (not shown), that also controls the operation of other components in the processing chamber 100.

FIG. 1B is an enlarged partial view of the substrate support assembly 101 of the processing chamber 100 of FIG. 1A, according to one or more embodiments. The substrate support assembly 101 includes a hybrid chuck 150 having both a chucking electrode 116 and a vacuum channel 119. The hybrid chuck 150 includes the chucking electrode 116 disposed inside a body 115 of the hybrid chuck 150 for chucking the substrate 102 disposed thereon. The chucking electrode 116 secures the substrate 102 to a chucking surface 151 during processing. The hybrid chuck 150 may be formed from a dielectric material, for example, a ceramic material, such as aluminum nitride (AlN) among other suitable materials. During an electrostatic chucking process, the hybrid chuck 150 implements the electrostatic attraction to hold the substrate 102 to the chucking surface 151. During the electrostatic chucking process, the hybrid chuck 150 acts as an electrostatic chuck (ESC).

The chucking electrode 116 is connected through a shaft 125 to a power source 117. The power source 117 is electrically coupled to the chucking electrode 116 through an isolation transformer 118 disposed between the power source 117 and the chucking electrode 116. The isolation transformer 118 may optionally be part of the power source 117. The power source 117 may apply a chucking voltage between about 50 Volts and about 5000 Volts to the chucking electrode 116. The hybrid chuck 150 may have a coating or layer disposed thereon configured to inhibit current leakage and reduce particle contamination within the processing chamber 100.

In some embodiments, an RF filtering circuit may be used in addition to, or instead of, the isolation transformer 118. The RF filtering circuit may be tuned to block out any parasitic RF components that may interfere with the power source 117, thus maximizing the chucking ability of the hybrid chuck 150. In one example, the RF filtering circuit may include a 50 nF inductor which filters out HFRF at approximately 13.56 MHz.

In some embodiments, the hybrid chuck 150 may be a Johnsen-Rahbeck (JR) mono-polar chuck which utilizes JR forces rather than Coulombic forces to chuck a substrate. When utilizing JR forces, chucking force increases with an increase in contact area and/or an increase in effective voltage (e.g., increased power supply and/or reduced leakage current). As described below, seasoning layers can affect the leakage current, and thus, can affect the chucking ability of an ESC.

The hybrid chuck 150 additionally includes a vacuum channel 119 fluidly coupled to a vacuum pump 162. The vacuum channel 119 extends though the hybrid chuck 150 and the shaft 125 to the chucking surface 151 of the hybrid chuck 150. An opening 152 of the vacuum channel is formed in the chucking surface 151 of the hybrid chuck 150. During a vacuum process a vacuum pressure is generated at the chucking surface 151 through the opening 152 by the vacuum pump 162 to chuck the substrate 102 to the chucking surface 151. In addition, the vacuum pressure from the vacuum pump 162 is utilized to stabilize the substrate 102 during processing.

The chucking surface 151 can include one or more channels 153 in fluid communication with the vacuum channel 119. The one or more channels 153 help enable substantially flat chucking of the substrate 102 by distributing the vacuum pressure across the chucking surface 151. The chucking surface 151 can additionally include grooves, ridges, or other structures to help distribute the vacuum pressure across the chucking surface 151 to help enable substantially flat chucking of the substrate 102.

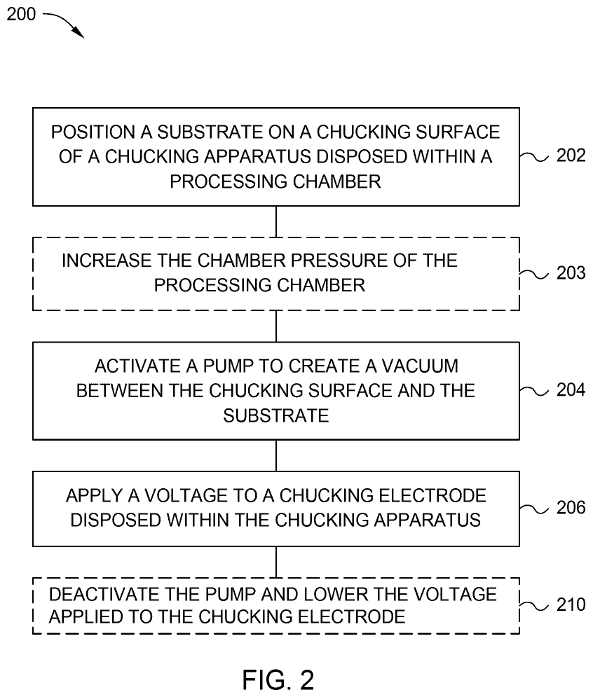

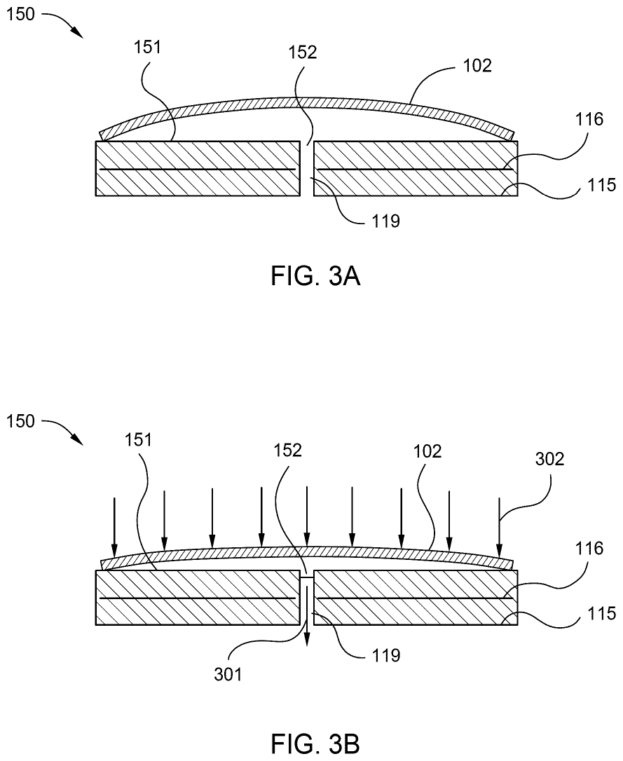

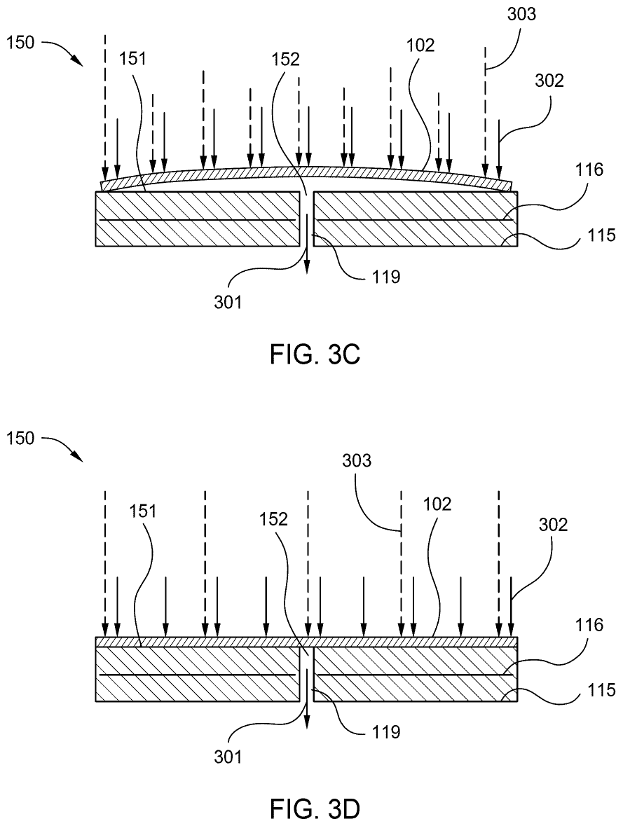

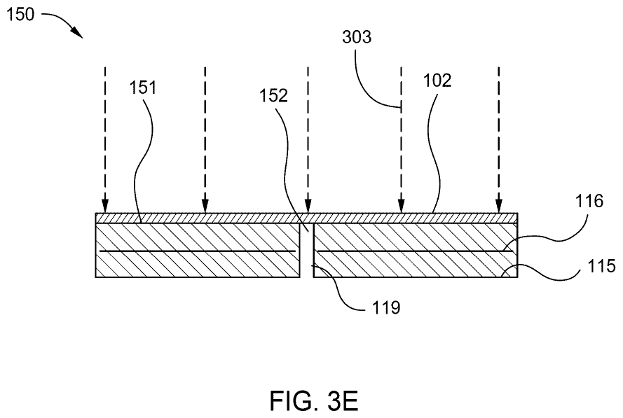

FIG. 2 is a flow diagram of a method 200 for chucking a substrate, according to one or more embodiments. The method 200 is described in conjunction with FIGS. 3A-3E. FIGS. 3A-3E, which show schematic cross sectional views of the hybrid chuck 150 of FIG. 1B during the method 200 of FIG. 2. It is to be understood, however, that the method 200 can be performed using any hybrid chuck and is not limited to the components described in FIGS. 3A-3E.

At operation 202, a substrate is positioned on a chucking surface of a chucking apparatus in a processing chamber. In some embodiments, the substrate has a compressive bow. The compressive bow of the substrate causes the outer edge of the substrate to contact a chucking surface of the chucking apparatus while also preventing the middle of the substrate from contacting the chucking surface. It should be understood that, although the method 200 is described as being performed with a substrate having a compressive bow, the method 200 can be performed using any substrate, including a substrate having a tensile bow or a flat substrate having no bow.

FIG. 3A shows the hybrid chuck 150 of FIG. 1B at operation 202. The substrate 102 has a compressive bow, which prevents the substrate 102 from lying flat against the chucking surface 151.

At operation 203 of method 200, the pressure within the processing chamber is increased relative to the chamber pressure during a processing operation. It should be noted that operation 203 is optional and, in various embodiments, can be excluded from the method 200, as indicated by the dashed lines in FIG. 2. The increased chamber pressure increases the pressure differential between the chucking surface and the substrate during operation 204. For example, if the chamber pressure of a processing chamber is normally about 3 mTorr, then the chamber pressure during operation 203 may be increased to a chamber pressure within a range of about 5 Torr to about 50 Torr. By increasing the chamber pressure, a greater pressure differential can be generated between the chamber pressure of the processing chamber and a vacuum pressure at the chucking surface of the chucking apparatus. The greater pressure differential enables additional force to be applied to the substrate, which helps flatten the substrate (e.g., so that the middle of the substrate is closer to the chucking surface).

At operation 204 of method 200, a pump is activated to create a vacuum between the chucking surface and the substrate. The vacuum pressure at the chucking surface is usually between 1 mTorr to 1000 mTorr. The pressure differential between the chucking surface and the substrate is lower than the chamber pressure of the processing chamber. For example, during operation 204, the pressure differential between the chucking surface and the substrate 102 could be within a range of about 1 mTorr to about 50 mTorr. The vacuum pulls the middle of the substrate towards the chucking surface, which helps flatten the substrate.

FIG. 3B shows the hybrid chuck 150 of FIG. 1B during operation 204, according to one or more embodiments. At operation 204, the vacuum pump 162 (FIG. 1B) is activated, creating a vacuum pressure 301 within the vacuum channel 119. The vacuum pressure 301 creates a lower pressure between the substrate 102 and the chucking surface 151 relative to the chamber pressure 302 of the processing chamber 100. As the vacuum pressure 301 is decreased, the pressure differential between the vacuum pressure 301 and the chamber pressure 302 is increased. This increased pressure differential causes the chamber pressure 302 to push against the substrate 102, flattening the substrate 102. The opening 152 of the vacuum channel 119 is generally in the center of the chucking surface 151, which causes the vacuum pressure 301 to pull the middle of the substrate 102 towards the chucking surface 151. The vacuum pressure 301 pulling the middle of the substrate 102 helps further flatten the substrate.

At operation 206, a voltage is applied to a chucking electrode disposed within the chucking apparatus. The chucking electrode creates an electrostatic force across the chucking surface. The electrostatic force pulls the substrate to the chucking surface. The electrostatic force increases as the distance of the substrate from the chucking surface decreases. Therefore, when a substrate has a compressive bow, the electrostatic force is stronger at the edges of the substrate contacting the chucking surface and weaker near the middle of the substrate, where the substrate not in contact with the chucking surface.

It is contemplated that operation 204 can be performed prior to operation 206 to partially flatten the substrate using vacuum chucking, prior to applying an electrostatic force to the substrate. For example, operation 204 may cause the substrate to partially flatten, which causes the middle of the substrate to be pulled closer to the chucking surface. Then, during operation 206, the electrostatic force applied to the middle of the vacuum chucked substrate is stronger as compared to the electrostatic force that would be applied to the middle of a substrate that has now been partially flattened during operation 204. The stronger electrostatic force allows a lower voltage to be applied to the chucking electrode, which may reduce or prevent arcing.

In various embodiments, the electrostatic force is substantially stronger than the vacuum pressure created in operation 204. This electrostatic force substantially flattens the substrate against the chucking surface by moving the middle of the substrate towards the chucking surface. In some embodiments, the middle of the substrate is pulled so that the middle of the substrate comes into contact with the chucking surface. The flattened substrate allows for the electrostatic force to be substantially uniform across the substrate. Therefore, the electrostatic force across the flattened substrate is stronger than the electrostatic force across a substrate with a compressive bow. The stronger electrostatic force across the flattened substrate allows voltage applied to the chucking electrode to be lowered once the substrate is substantially flat at an operation 210 of method 200. The lower voltage at operation 210 helps prevent arcing. It is contemplated that, in some embodiments, operations 204 and 206 are performed simultaneously, or that operation 206 is performed prior to operation 204.

FIG. 3C shows the hybrid chuck 150 of FIG. 1B during operation 206, according to one or more embodiments. At operation 206, a voltage is applied to the chucking electrode 116. The chucking electrode creates an electrostatic force 303 across the chucking surface 151. The electrostatic force 303 pulls the substrate 102 towards the chucking surface 151. However, the substrate 102 is not completely flat. Instead, the outer edge of the substrate 102 contacts the chucking surface 151, and the middle of the substrate 102 is not in contact with the chucking surface 151 due to the compressive bow of the substrate 102. The electrostatic force 303 is stronger at the edge of the substrate 102 where the substrate 102 is in contact with the chucking surface 151. The electrostatic force 303 is weaker at the middle of the substrate where the substrate 102 is not in contact with the chucking surface 151.

FIG. 3D shows the hybrid chuck 150 of FIG. 1B after operation 206, according to one or more embodiments. After operation 206, the electrostatic force 303 causes the substrate 102 to be substantially flattened against the chucking surface 151. The even contact across the substrate causes the electrostatic force 303 to be more evenly distributed across the substrate 102. This more even distribution of the electrostatic force 303 allows the substrate to be securely fixed against the chucking surface 151 of the hybrid chuck 150. The electrostatic force 303 against the substrate is equivalent to a pressure that is greater than 30 Torr, such as greater than 35 Torr, such as greater than 45 Torr. The electrostatic force 303 chucks the substrate to the chucking apparatus for processing.

At operation 210, the pump may be deactivated. It should be noted that operation 210 is optional and, in various embodiments, can be excluded from the method 200. Operation 210 is performed after operation 206. In various embodiments, at operation 210, only the electrostatic force is used to keep the substrate chucked against the chucking surface. In some embodiments, the chamber pressure is then decreased for a processing operation. For example, in some embodiments, the chamber pressure at operations 204-210 is at a higher pressure, such as a pressure within a range of about 20 Torr to about 40 Torr, in order to help chuck the substrate to the chucking surface. At operation 210, the chamber pressure may be decreased to a processing pressure, for example, within a range about 3 Torr to about 10 Torr. When the chamber pressure is decreased, the substrate remains chucked to the chucking apparatus due to the strong electrostatic force created by the chucking electrode. After the substrate has been substantially flattened, the voltage applied across the chucking electrode may be lowered to prevent arcing.

FIG. 3E shows the hybrid chuck 150 of FIG. 1B during operation 210. The substrate 102 is chucked flat against the chucking surface 151 due to the electrostatic force 303. When the substrate 102 is flattened, the electrostatic force 303 is strong enough to allow for the vacuum pump 162 that creates the vacuum pressure 301 to be deactivated. Additionally, the electrostatic force 303 is strong enough to allow the voltage across the chucking electrode to be decreased to prevent arcing. In some embodiments, the chamber pressure of the processing chamber 100 is decreased for a processing operation.

Benefits of the present disclosure include increased vacuum pressure; increased electrostatic force; increased chucking pressure; decreased voltage; decreased arcing; increased efficiency; decreased maintenance; decreased cost; decreased substrate bow; and improved substrate processing performance.

It is contemplated that one or more aspects disclosed herein may be combined. As an example, one or more aspects, features, components, operations and/or properties of the processing chamber 100, the substrate support assembly 101, the substrate 102, the chamber pump 109, the hybrid chuck 150, the chucking electrode 116, the body 115, the chucking surface 151, the vacuum channel 119, the power source 117, the isolation transformer 118, the shaft 125, the opening 152, the vacuum pump 162, the one or more channels 153, and/or method 200 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

1. A substrate chucking apparatus, comprising:
a body having a chucking surface;
a shaft coupled to the body opposite to the chucking surface;
a chucking electrode disposed within the body; and
a vacuum channel formed within the body.

2. The substrate chucking apparatus of claim 1, wherein the chucking surface comprises on or more channels in fluid communication with the vacuum channel.

3. The substrate chucking apparatus of claim 1, further comprising a plurality of grooves or ridges formed on the chucking surface.

4. The substrate chucking apparatus of claim 1, wherein the vacuum channel further comprises an opening located in the center of the chucking surface.

5. The substrate chucking apparatus of claim 1, further comprising:
a pump fluidly coupled to the vacuum channel.

6. The substrate chucking apparatus of claim 1, wherein the body is formed of a dielectric material.

7. A substrate processing chamber, comprising:
a chamber body, the chamber body at least partially defining a processing region;
a chamber pump fluidly coupled to the processing region; and
substrate chucking apparatus, the substrate chucking apparatus having a chucking surface;
a shaft coupled to the substrate chucking apparatus opposite to the chucking surface
a chucking electrode disposed within the substrate chucking apparatus; and
a vacuum channel formed within the substrate chucking apparatus.

8. The substrate processing chamber of claim 7, wherein the chucking surface comprises on or more channels in fluid communication with the vacuum channel.

9. The substrate chucking apparatus of claim 7, wherein the chucking surface comprises a plurality of grooves or ridges formed on the chucking surface.

10. The substrate processing chamber of claim 7, wherein the substrate support assembly further comprises a power source electrically coupled to the chucking electrode.

11. The substrate processing chamber of claim 7, wherein the substrate support assembly further comprises a vacuum pump fluidly coupled to the vacuum channel.

12. A method of chucking a substrate, comprising:
positioning a substrate on a chucking surface of a chucking apparatus disposed within a processing chamber;
activating a pump to create a vacuum between the chucking surface and the substrate; and
applying a voltage to a chucking electrode disposed within the chucking apparatus to chuck the substrate to the chucking surface.

13. The method of claim 12, further comprising prior to applying the voltage to the chucking electrode, increasing a chamber pressure of the processing chamber.

14. The method of claim 12 further comprising after applying the voltage to the chucking electrode, deactivating the pump.

15. The method of claim 12, wherein the substrate has a compressive bow so that the center of the substrate is a distance from the chucking surface and an edge of the substrate contacts the chucking surface.

16. The method of claim 15, wherein activating the pump to create the vacuum between the chucking surface and the substrate causes the center of the substrate to move towards the chucking surface.

17. The method of claim 15, wherein applying the voltage to the chucking electrode causes the center of the substrate to move towards the chucking surface.

18. The method of claim 17, further comprising decreasing the voltage applied to the chucking electrode after the center of the substrate is moved towards the chucking surface.

19. The method of claim 12, wherein activating the pump to create the vacuum between the chucking surface and the substrate is performed substantially simultaneously with applying the voltage to the chucking electrode disposed within the chucking apparatus.

20. The method of claim 12, wherein activating the pump to create the vacuum between the chucking surface and the substrate is performed prior to applying the voltage to the chucking electrode.
